(19) United States
(12) Patent Application Publication
(10) Pub. No.: US 2020/0120787 A1
(43) Pub. Date: Apr. 16, 2020

(54) ELECTRONIC DEVICE

(71) Applicant: InnoLux Corporation, Miao-Li County (TW)

(72) Inventors: Yu-Hsin FENG, Miao-Li County (TW); Wei-Hsin CHAIO, Miao-Li County (TW); Yu-Tse LU, Miao-Li County (TW); Wei-Ting CHOU, Miao-Li County (TW)

(21) Appl. No.: 16/560,081

(22) Filed: Sep. 4, 2019

(30) Foreign Application Priority Data
Oct. 16, 2018 (CN) 201811201611.7

(51) Int. Cl. H05K 1/02; H03H 7/38

(52) U.S. Cl. CPC H05K 1/025; H05K 2201/09727; H03H 7/38; H05K 1/0216

(57) ABSTRACT

The present disclosure relates to an electronic device. The electronic device includes a circuit board. The circuit board includes a wiring layer and a patterned electrode layer. The wiring layer includes a plurality of wires. One of the wires includes a trace part and a terminal part connected to the trace part. The patterned electrode layer is disposed opposite to the wiring layer. The trace part and the patterned electrode layer have a first overlapping area, the terminal part and the patterned electrode layer have a second overlapping area, and a ratio of the first overlapping area to the second overlapping area is between 0.7 and 1.3.

### CROSS REFERENCE TO RELATED APPLICATION

This application claims the benefits of China Patent Application Serial Number 201811201611.7, filed on Oct. 16, 2018, the subject matter of which is incorporated herein by reference.

### BACKGROUND

### 1. Technical Field

The present disclosure relates to an electronic device, and particularly to an electronic device that improves impedance matching of wires of a circuit board.

### 2. Description of Related Art

Electronic devices have been developed to achieve high speed signal transmission or high resolution. As a common problem for a circuit board of an electronic device, signal reflection or signal jitter may occur in the transmission process to affect the signal transmission quality. Significant impedance difference (or impedance mismatch) between different segments of a wire of the circuit board is believed to be a possible cause of this problem. It remains a question about how to reduce the impedance difference between the different segments of the wire.

### SUMMARY

The present disclosure provides an electronic device that can reduce the impedance difference between different segments of a wire by designing a wiring layer and an electrode layer of a circuit board.

An electronic device of the present disclosure includes a circuit board. The circuit board includes a wiring layer and a patterned electrode layer opposite to the wiring layer. The wiring layer includes a plurality of wires. One of the wires includes a trace part and a terminal part connected to the trace part. The trace part and the patterned electrode layer have a first overlapping area, the terminal part and the patterned electrode layer has a second overlapping area, and a ratio of the first overlapping area to the second overlapping area is between 0.7 and 1.3.

Another electronic device of the present disclosure includes a circuit board. The circuit board includes a wiring layer. The wiring layer includes a first reference wire, a second reference wire, a first group of wires, and a second group of wires. The second group of wires is adjacent to the first group of wires, and the first group of wires and the second group of wires are located between the first reference wire and the second reference wire.

Other objects, advantages, and novel features of the present disclosure will be more apparent from the following description when taken in conjunction with the accompanying drawings.

### BRIEF DESCRIPTION OF THE DRAWINGS

FIG. 1 is a schematic diagram of the electronic device according to one embodiment of the present disclosure;

FIG. 2A is a perspective view of a first type of circuit board of the electronic device according to one embodiment of the present disclosure;

FIG. 2B is a schematic diagram showing a detailed structure of one group of wires in the wiring layer of FIG. 2A;

FIG. 2C is a graph showing the relationship between impedance and time measured by a time-domain reflectometer (TDR) for the circuit board of FIG. 2A according to one embodiment of the present disclosure;

FIG. 3 is a schematic diagram of the first type of circuit board of the electronic device according to another embodiment of the present disclosure;

FIG. 4A is a perspective view of a second type of circuit board of the electronic device according to one embodiment of the present disclosure;

FIG. 4B is a top view in Z-direction of the circuit board of FIG. 4A;

FIG. 5A is a top view in Z-direction of the second type of circuit board of the electronic device according to another embodiment of the present disclosure;

FIG. 5B is a top view in Z-direction of the second type of circuit board of the electronic device according to still another embodiment of the present disclosure;

FIG. 5C is a top view in Z-direction of the second type of circuit board of the electronic device according to still another embodiment of the present disclosure;

FIG. 5D is a top view in Z-direction of the second type of circuit board of the electronic device according to still another embodiment of the present disclosure;

FIG. 5E is a top view in Z-direction of the second type of circuit board of the electronic device according to still another embodiment of the present disclosure;

FIG. 5F is a top view in Z-direction of the second type of circuit board of the electronic device according to still another embodiment of the present disclosure; and

FIG. 6 is a graph showing a relationship between impedance and time measured by TDR for the second type of circuit board according to one embodiment of the present disclosure.

### DETAILED DESCRIPTION OF THE EMBODIMENT

Different embodiments are provided in the following description for the person skilled in this art to understand the advantages and the effects in the present disclosure. More embodiments may be realized in different aspects or for different applications by modifying or varying the provided embodiments without departing from the spirit and scope of the present disclosure.

The ordinal numbers such as “first” or “second” added before the elements in the present disclosure are used to distinguish two elements having the same name. They do not necessarily imply the arrangement orders or the manufacture orders of the two elements. One element with a greater ordinal number does not necessarily imply the existence of another element with a smaller ordinal number.

The descriptions such as “disposed on” in the present disclosure are used to describe the relative locations between two elements. They do not imply the contact of the two elements, unless otherwise specified. The terms such as “connected”, “electrically connected”, or “coupled” in the present disclosure refer to direct connection and indirect connection, unless otherwise specified.

The term “about” or “substantially” means a value or a range with a 20%, 10%, or 5% variation. The meaning of “about” or “substantially” is still applied to a value or a range, even if it is not described with “about”, unless otherwise specified.

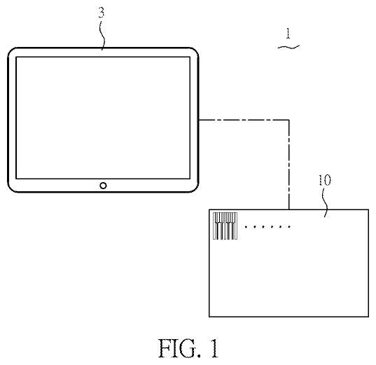

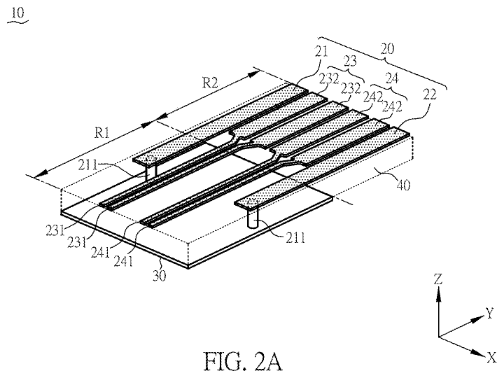

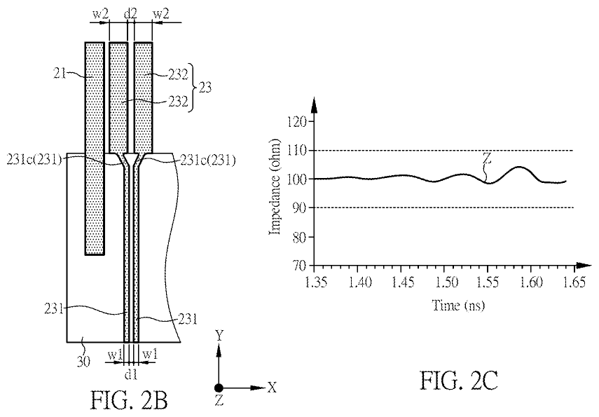

Referring to both FIGS. 1 and 2A, FIG. 1 is a schematic diagram of the electronic device 1 according to one embodiment of the present disclosure. FIG. 2A is a perspective view of a first type of circuit board 10 of the electronic device 1 according to one embodiment of the present disclosure. As shown in FIGS. 1 and 2A, the electronic device 1 includes a panel 3 and a circuit board 10. In one embodiment, the circuit board 10 includes a wiring layer 20. The wiring layer 20 includes a first reference wire 21, a second reference wire 22, a first group of wires 23, and a second group of wires 24. Y-direction refers to the extending direction of the first group of wires 23 (and/or the second group of wires 24), Z-direction refers to the normal direction of the circuit board 10 (for looking down at the circuit board), and X-direction is substantially perpendicular to both of Y-direction and Z-direction. The first group of wires 23 is adjacent to the second group of wires 24 in X-direction, and the first group of wires 23 and the second group of wires 24 are located between the first reference wire 21 and the second reference wire 22. In other words, the first reference wire 21, the first group of wires 23, the second group of wires 24, and the second reference wire 22 are disposed in order in X-direction. In other embodiments, more groups of wires may be located between the first reference wire 21 and the second reference wire 22.

The electronic device 1 of the present disclosure may be a display device, a lighting device, a communication device, a detecting device, an antenna device, a tiled device, or any other electronic device, but not limited thereto. The electronic device 1 may use the circuit board 10 to transmit signals in low speed, medium speed, or high speed, but not limited thereto.

The electronic device 1 may include an organic light emitting diode (OLED), a quantum dot organic light emitting diode (QOLED), a quantum dot light emitting diode (QLED), an (inorganic) light emitting diode (LED), a micro LED (in micro-meter size), or a mini LED (in mini-meter size), and may include quantum dots, fluorescence material, or phosphor material, but not limited thereto. The circuit board 10 may be a flexible circuit board or an inflexible circuit board, but not limited thereto. The circuit board 10 may be a printed circuit board (PCB), a chip on film (COF), or a flexible printed circuit (FPC), but not limited thereto.

In one embodiment, the circuit board 10 may be a multilayer circuit board. The circuit board 10 may have a multilayer structure including a wiring layer 20, an electrode layer 30, a dielectric layer 40, an adhesive layer (not shown), a substrate (not shown), or any other layer or component, but not limited thereto. It should be noted that, FIG. 2A only shows a simplified structure of the circuit board 10, wherein one wiring layer 20, one electrode layer 30, and one dielectric layer 40 are shown. However, a person skilled in this art may realize that the circuit board 10 may include at least one wiring layer 20, at least one electrode layer 30, and at least one dielectric layer 40. In other embodiments, the circuit board 10 may include more layers, such as the adhesive layer, the substrate, or any other layer or component, but not limited thereto, depending on practical requirements. The sizes, such as the thicknesses, the widths, the pitches, or the shapes of the layers are illustratively shown in the drawings of the present disclosure, but not meant to be limiting, and they are adjustable according to practical applications.

As shown in FIG. 2A, the electrode layer 30 is disposed opposite to the wiring layer 20 in Z-direction. The dielectric layer 40 is disposed between the wiring layer 20 and the electrode layer 30. In one embodiment, at least one adhesive layer may be disposed between the wiring layer 20 and the dielectric layer 40, or between the electrode layer 30 and dielectric layer 40 in Z-direction, but not limited thereto. The adhesive layer may include acrylic, epoxy, optically clear adhesive (OCA), optical clear resin (OCR), any other suitable material, or their combinations, but not limited thereto. The adhesive layer may have a thickness between 0.3 mm and 2.5 mm, i.e. 0.3 mm≤thickness≤2.5 mm, but not limited thereto.

In one embodiment, the wiring layer 20 or the electrode layer 30 may include copper, aluminum, gold, silver, aluminum, molybdenum, tungsten, chrome, nickel, titanium, any other suitable conductive material, or their combinations, or may include any other conductive material having good conductivity or small resistance, but not limited thereto. Moreover, the wiring layer 20 and the electrode layer 30 may be made of the same material or different materials. The dielectric layer 40 may include high impedance material or insulating material, such as polyimide, polyethylene terephthalate (PET), resin, any other suitable material, or their combinations, but not limited thereto. In one embodiment, the wiring layer 20 may have a thickness (in Z-direction) between 0.005 mm and 1 mm, i.e. 0.005 mm≤thickness≤1 mm, particularly about 0.018 mm. In one embodiment, the electrode layer 30 may have a thickness (in Z-direction) between 0.005 mm and 1 mm, i.e. 0.005 mm≤thickness≤1 mm, particularly about 0.018 mm. In one embodiment, the dielectric layer 40 may have a thickness (in Z-direction) between 0.005 mm and 1 mm, i.e. 0.005 mm≤thickness≤1 mm, particularly about 0.045 mm. In one embodiment, the electrode layer 30 and the wiring layer 20 may be separated by a distance (in Z-direction) between 0.005 mm and 1 mm, i.e. 0.005 mm≤thickness≤1 mm, particularly about 0.045 mm, but not limited thereto. The thicknesses of each layer or each component may be defined, for example, in a sectional view of the layer or the component from a scanning electron microscope (SEM) image. The SEM image may have a width and/or a thickness between 0.001 mm and 2 mm in a local region. The thicknesses of the layer or the component may be defined based on the greatest thickness of the layer or the component in the SEM image. The thicknesses may also be defined by any other suitable measurement. However, the SEM image may have another range of the width and/or the thickness in the local region, adjustable depending on the real thickness of the layer or the component.

As shown in FIG. 2A, the circuit board 10 has a trace region R1 and a terminal region R2 in Y-direction. The electrode layer 30 is disposed in the trace region R1. The wiring layer 20 (including the first reference wire 21, the second reference wire 22, the first group of wires 23, and the second group of wires 24) is disposed partially in trace region R1 and partially in terminal region R2. Moreover, the first reference wire 21 and the second reference wire 22 are electrically connected to the electrode layer 30. In one embodiment, the first reference wire 21 and the second reference wire 22 may be electrically connected to the electrode layer 30 through a via-hole 211. For example, the dielectric layer 40 is formed with a hole, and conductive material is then disposed inside the hole, so as to form the via-hole 211, but not limited thereto. Moreover, the hole may be disposed with the conductive material that is the same as or different from that of the wiring layer 20 or the electrode layer 30.

The electrode layer 30 may serve as a voltage reference layer. In one embodiment, the electrode layer 30 may have zero voltage, and thus serve as a ground layer, and the first reference wire 21 and the second reference wire 22 may also have zero voltage because of their connections to the electrode layer 30. In one embodiment, the electrode layer 30 may have a negative voltage, and serve as a negative voltage reference layer, and the first reference wire 21 and the second reference wire 22 may also have the negative voltage because of their connections to the electrode layer 30. In one embodiment, the electrode layer 30 may serve as a reference layer for impedance matching, and have a suitable reference voltage, such as a negative voltage, a zero voltage, or a positive voltage.

In one embodiment, as shown in FIG. 2A, each of the first group of wires 23 and the second group of wires 24 includes two wires. In one embodiment, the two wires of the first group of wires 23 (and/or the second group of wires 24) may be used to transmit differential signals. For example, the first group of wires 23 (and/or the second group of wires 24) has one wire to transmit a positive differential signal, and another wire to transmit a negative differential signal. The positive differential signal and the negative differential signal may have substantially equal amplitude, but not limited thereto. In another embodiment, each of the two wires in the first group of wires 23 (and/or the second group of wires 24) may be a single-ended wire, and the two wires may be used to transmit their respective single-ended signals. In one embodiment, the two wires in the first group of wires 23 (and/or the second group of wires 24) may be symmetric (e.g. mirror-symmetric) in Y-direction, but not limited thereto. It should be noted that, FIG. 2A only shows the first group of wires 23 and the second group of wires 24 between the first reference wire 21 and the second reference wire 22. However, in other embodiments, more groups of wires may be disposed between the first reference wire 21 and the second reference wire 22, and therefore more signal wires may be realized in the circuit board of a fixed size. Moreover, a wire of the first group of wires 23 (and/or the second group of wires 24) has a part located in the trace region R1, which is called a trace part 231 (and/or a trace part 241), and another part located in the terminal region R2, which is called a terminal part 232 (and/or a terminal part 242). The trace part 231 (and/or the trace part 241) is connected to the terminal part 232 (and/or the terminal part 242). In one embodiment, the terminal part 232 (and/or the terminal part 242) may be connected to a conductive pad of a connector or a conductive pad on a panel of the electronic device, but not limited thereto. For example, the terminal part 232 (and/or the terminal part 242) may be connected to a pin of the connector, but not limited thereto. The terminal part 232 (and/or the terminal part 242) of the circuit board 10 may directly or indirectly contact the conductive pad of the connector or the conductive pad on the panel of the electronic device. For example, the terminal part 232 (and/or the terminal part 242) of the circuit board may be clamped by the connector, and directly contact or be electrically connected to the conductive pad of the connector. In some embodiments, the terminal part 232 (and/or the terminal part 242) of the circuit board 10 may be electrically connected to the conductive pad on the panel of the electronic device via a conductive component, but not limited thereto. The conductive component may include an anisotropic conductive film (ACF), tin, gold, any other suitable conductive material, but not limited thereto. The terminal part 232 and the terminal part 242 of the circuit board 10 may be connected to the panel via the connector or the conductive component, but not limited thereto. The signal may be transmitted via the trace part 231 (and/or the trace part 241) of the circuit board, and sent to the panel via the terminal part 232 (and/or the terminal part 242), but not limited thereto. The panel may be a display panel, a touch panel, a sensor (or detector) panel, a lighting panel, an antenna panel, or a tiled panel, but not limited thereto.

In some embodiments, the terminal region R2 of the circuit board may be provided with a stiffener. The stiffener may include polyimide (PI), polyethylene terephthalate (PET), fiberglass (FR4), stainless steel (SUS), resin, any other suitable material, or their combinations, but not limited thereto. In one embodiment, the stiffener may have a thickness about 75 μm in Z-direction, but not limited thereto. In some embodiments, the stiffener may serve as a reinforcement board or a support board in the terminal region of the circuit board to prevent the terminal part from breakage or damage.

Retelling to both FIGS. 2A and 2B. FIG. 2B is a schematic diagram showing a detailed structure of one group of wires (e.g. the first group of wires 23 or the second group of wires 24) in the wiring layer 20 of FIG. 2A. As shown in FIG. 2B, the trace part 231 and the terminal part 232 have different widths in X-direction. In one embodiment, the trace part 231 (and/or the trace part 241) may have a width w1 between 10 μm and 1000 μm, i.e. 10 μm≤w1≤1000 μm, particularly about 67 μm. The width w1 may be defined to be the greatest width of the trace part 231 (and/or the trace part 241) in X-direction of a local region. In one embodiment, the terminal part 232 (and/or the terminal part 242) may have a width w2 between 100 μm and 3000 μm, i.e. 100 μm≤w2≤3000 μm, particularly about 350 μm. The width w2 may be defined to be the greatest width of the terminal part 232 (and/or the terminal part 242) in X-direction of a local region. In one embodiment, in the first group of wires 23 (and/or the second group of wires 24), two adjacent trace parts 231 (and/or two adjacent trace parts 241) may have a pitch d1 between 50 μm and 50000 μm, i.e. 50 μm≤d1≤50000 μm, particularly about 133 μm. The pitch d1 may be defined to be the smallest distance between the two adjacent trace parts 231 (and/or the two adjacent trace parts 241) in X-direction of a local region. In one embodiment, in the first group of wires 23 (and/or the second group of wires 24), the two adjacent terminal parts 232 (and/or the two adjacent terminal parts 242) may have a pitch d2 between 50 μm and 50000 μm, i.e. 50 μm≤d2≤50000 μm, particularly about 150 μm. The pitch d2 may be defined to be the smallest distance between the two adjacent terminal parts 232 (and/or the two adjacent terminal parts 242) in X-direction of a local region. It should be noted that, the greatest width or the greatest pitch of the component in the local region may be defined based on the greatest width of the component measured in an optical microscopy (OM) image, wherein the image may be set to have a length and a width between 0.5 mm and 500 mm. Any other suitable measurement is also applicable. In one embodiment, the ratio of the width w2 to the width w1 may be substantially equal to or greater than 1.2, i.e. 1.2≤w2/w1, but not limited thereto. In one embodiment, the ratio of the width w2 to the width W1 may be between 0.8 and 1.2, i.e. 0.8≤w2/w1≤1.2.

In one embodiment, when the first group of wires 23 or the second group of wires 24 serves as differential wires, the trace part 231 (and/or the trace part 241) has a first differential impedance, and the terminal part 232 (and/or the terminal part 242) has a second differential impedance. In the conventional circuit board, the trace part 231 (and/or the trace part 241) and the terminal part 232 (and/or the terminal part 242), typically have different widths w1 and w2, or different pitches d1 and d2, such that the first differential impedance is different from the second differential impedance. For example, the second differential impedance may be less (or smaller) than the first differential impedance. A difference between the second differential impedance and the first differential impedance that is equal to or greater than 20 ohm may result in signal reflection or signal jitter in the transmission process. However, in the embodiments of the present disclosure, the electrode layer 30 is disposed in the trace region R1, and no electrode layer 30 exists in the terminal region R2, so the terminal part 232 and the terminal part 242 does not overlap the electrode layer 30 in Z-direction. This can reduce the impedance difference (and the differential impedance) in the trace part and the terminal part, and improve the signal transmission quality.

The following description will discuss FIGS. 2A to 2C in detail. FIG. 2C is a graph showing the relationship between impedance (e.g. differential impedance) and time measured by TDR for the circuit board 10 of FIG. 2A according to one embodiment of the present disclosure. The impedance-time curve shows how the impedance changes from the trace part to the terminal part when the signal transmitted from the trace part 231 (and/or the trace part 241) to the terminal part 232 (and/or the terminal part 242). The impedance Z in FIG. 2C may correspond to the impedance in the terminal part. As shown in FIG. 2C, the impedance Z is between 90 ohm (Ω) and 110 ohm (Ω), i.e. 90Ω≤Z≤110 n, and the ratio of the first (differential) impedance to the second (differential) impedance is between 0.9 and 1.1, i.e. 0.9≤ratio≤1.1, but not limited thereto. In some embodiments, the ratio of the first (differential) impedance to the second (differential) impedance is between 0.92 and 1.08, i.e. 0.92≤ratio≤1.08. The present disclosure provides a design that can reduce the impedance difference in the trace part and the terminal part, and the differential impedance, improve the impedance matching, and solve the problem of signal reflection or signal jitter in the circuit board. It should be noted that, it is only an example in the present disclosure to use the time to correspond to the terminal part in the TDR graph. The correspondence should be adjusted depending on the real length of the wire.

Moreover, in FIG. 2A, the electrode layer 30 is substantially disposed in the trace region R1, but not limited thereto. The electrode layer 30 may have different types.

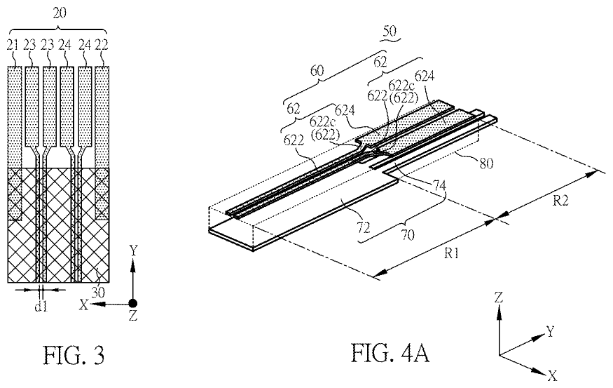

FIG. 3 is a schematic diagram of the first type of circuit board 10 according to another embodiment of the present disclosure. As shown in FIG. 3, the electrode layer 30 may have a mesh pattern, e.g. including a plurality of openings arranged in an array. In FIG. 3, an opening of the electrode layer 30 has a rhombus shape in Z-direction, and the openings substantially have the same shape, but not limited thereto. In other embodiments, an opening of the electrode layer 30 may have an arc shape, a polygon shape, or any other irregular shape. In other embodiments, the openings of the electrode layer 30 may be arranged in an array or not. In other embodiments, different electrode layers 30 may have their respective openings of the same size or different sizes. Moreover, the wiring layer 20 in the embodiment of FIG. 3 may be applied with the similar design for the wiring layer 20 of the embodiment of FIGS. 2A and 2B, and will not be discussed again here. The design for the circuit board 10 in FIG. 3 can reduce the impedance difference (and the differential impedance) in the trace part and the terminal part, and improve the signal transmission quality.

It should be noted that, the boundary between the terminal region R2 and the trace region R1 does not limit the location of the electrode layer 30. In some embodiments, the trace part 231 may partially not overlap the electrode layer 30. For example, a pitch d1 between two adjacent trace parts may vary. Two adjacent trace parts may have their respective connecting portions 231c that are connected to (and near) their respective terminal parts 232, and a greater pitch d1 may appear between the two connecting portions 231c. The electrode layer 30 may partially or completely overlap or may not overlap the connecting portion 231c. In some embodiments, the electrode layer 30 may not overlap the connecting portion 231c. In some embodiments, the electrode layer 30 may at least partially overlap the connecting portion 231c.

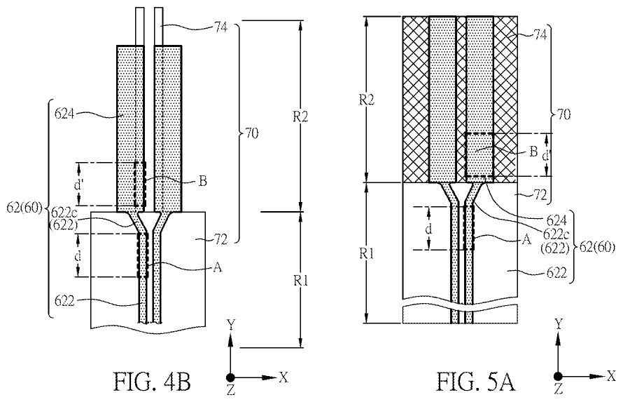

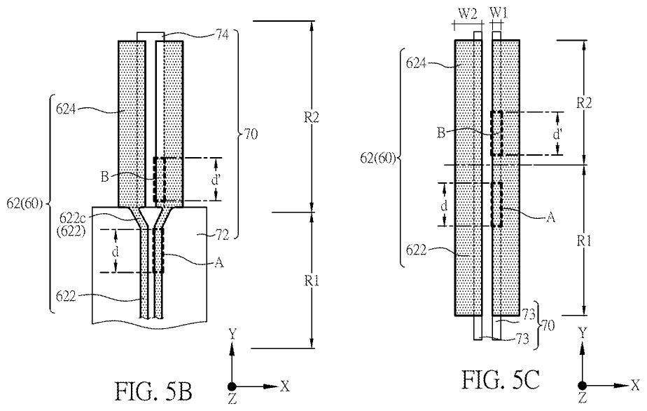

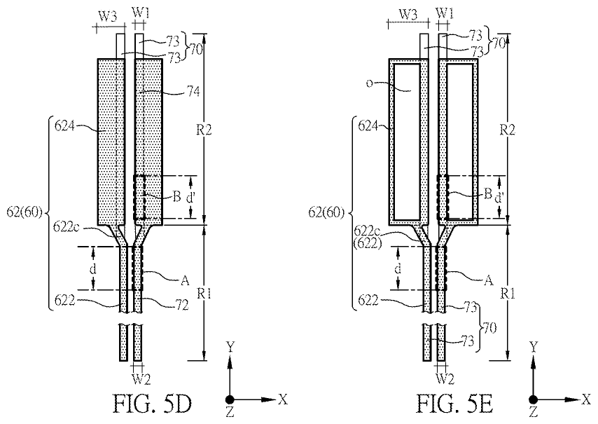

The circuit board of the present disclosure may have various types. The following description will discuss a second type of circuit board 50 of the present disclosure in conjunction with FIGS. 4A to 5F. FIG. 4A is a perspective view of the second type of circuit board 50 of the electronic device 1 according to one embodiment of the present disclosure. FIG. 4B is a top view in Z-direction of the circuit board 50 of FIG. 4A. MS. 5A to 5F are top views in Z-direction of the second type of circuit board 50 according to various embodiments of the present disclosure.

As shown in FIGS. 4A to 5F, the second type of circuit board 50 includes a wiring layer 60 and a patterned electrode layer 70. The wiring layer 60 includes a plurality of wires 62. One of the wires 62 includes a trace part 622 and a terminal part 624 connected to the trace part 622. The patterned electrode layer 70 is disposed opposite to the wiring layer 60 in Z-direction. A dielectric layer 80 may be disposed between the patterned electrode layer 70 and the wiring layer 60 in Z-direction. Y-direction refers to the extending direction of the wire 62, Z-direction refers to the normal direction of the circuit board 50 (for looking down at the circuit board), and X-direction is substantially perpendicular to both of Y-direction and Z-direction, but not limited thereto. In other embodiments, more dielectric layers may be disposed between the patterned electrode layer 70 and the wiring layer 60 depending on practical applications. In other embodiments, more adhesive layers may be disposed between the patterned electrode layer 70 and the wiring layer 60 depending on practical applications. In other embodiments, there may be two or more patterned electrode layers 70, and/or two or more wiring layers 60. As shown in FIG. 4A, the wiring layer 60 and the patterned electrode layer 70 are disposed on two opposite sides of the dielectric layer 80, respectively. The dielectric layer 80 is represented by a region surrounded by dotted lines. As shown in FIGS. 4B to 5F, the trace part 622 and the patterned electrode layer 70 has a first overlapping area A in Z-direction, the terminal part 624 and the patterned electrode layer 70 has a second overlapping area B, and the ratio of the first overlapping area A to the second overlapping area B is between 0.7 and 1.3, i.e. 0.7≤A/B≤1.3), but not limited thereto. In some embodiments, the ratio of the first overlapping area A to the second overlapping area. B is between 0.8 and 1.2, i.e. 0.8≤A/B≤1.2. In some embodiments, the ratio of the first overlapping area A to the second overlapping area B is between 0.9 and 1.1, i.e. 0.9≤A/B≤1.1.

It should be noted that, the first overlapping area A and the second overlapping area B are measured in substantially equal lengths of wires 62. In particularly, as shown in FIG. 4B, the respective overlapping areas of the trace part 622 and terminal part 624 overlapping the patterned electrode layer 70 are measured in substantially equal lengths of wires 62. For example, after respective equal areas are selected for the trace part 622 and the terminal part 624 the first overlapping area A can be measured as the overlapping area of the selected area of the trace part 622 overlapping the patterned electrode layer 70 in Z-direction, and the second overlapping area B can be measure as the overlapping area of the selected area of the terminal part 624 overlapping the patterned electrode layer 70 in Z-direction. The length of the wire 62 may be measured in the extending direction of the wire 62, i.e. Y-direction. In other words, for example, a length d is selected in the overlapping portion of the trace part 622 and the patterned electrode layer 70, and the overlapping area of the trace part 622 and the patterned electrode layer 70 in Z-direction within the length d is defined to be the first overlapping area A. Then, a length d′ is selected in the overlapping portion of the terminal part 624 and the patterned electrode layer 70, the length d′ being substantially equal to the length d in Y-direction, and the overlapping area of the terminal part 624 and the patterned electrode layer 70 within the length d′ is defined to be the second overlapping area B. In some embodiments, the length d is between 0.3 cm and 1 cm, i.e. 0.3 cm≤d≤1 cm, but not limited thereto.

In the second type of circuit board 50, the first overlapping area A and the second overlapping area B are adjusted such that the ratio of the first overlapping area A and the second overlapping area B is between 0.7 and 1.3, i.e. 0.7≤A/B≤1.3. Accordingly, the capacitance between the patterned electrode layer 70 and the terminal part 624 is substantially equal to the capacitance between the patterned electrode layer 70 and the trace part 622. This can reduce the impedance difference (and the differential impedance) in the trace part and the terminal part, and improve the signal transmission quality.

Moreover, the second type of circuit board 50 may be applied with the similar design for the first type of circuit board 10 regarding the materials or the sizes (such as the thicknesses, the pitches, the distances, and so on) of the layers, unless otherwise specified. For example, the wiring layer 60 may be made of the material for the wiring layer 20. The patterned electrode layer 70 may be made of the material for the electrode layer 30. The patterned electrode layer 70 may also serve as a voltage reference layer, such as a ground layer or a negative voltage reference layer. The dielectric layer 80 may be applied with the similar design for the dielectric layer 40. They will not be discussed again here. The parameters in this embodiment, such as the pitch between the two adjacent trace parts 622 in the wiring layer 60 (referring to the pitch d1 in FIG. 2B), the pitch between the two adjacent terminal parts 624 in wiring layer 60 (referring to the pitch d2 in FIG. 2B), the thickness of the wiring layer 60, the thickness of the dielectric layer 80, the thickness of the patterned electrode layer 70, the width of the trace part 62 in X-direction (referring to the width w1 in FIG. 2B), the width of the terminal part 624 in X-direction (referring to the width w2 in FIG. 2B) may refer to the design for the embodiment of FIGS. 2A and 2B, and will not be discussed again here.

In one embodiment, the two wires 62 in the wiring layer 60 may be a set of differential wires, but not limited thereto, while, in one embodiment, each of the wires 62 may be single-ended wire.

It should be noted that, one difference between the second type of circuit board 50 and the first type of circuit board 10 is that: in the first type of circuit board 10, the electrode layer 30 is located in the trace region R1, while, in the second type of circuit board 50, the patterned electrode layer 70 is located in both of the trace region R1 and the terminal region R2.

Moreover, as shown in FIGS. 4A, 4B, 5E, and 5F, the patterned electrode layer 70 has a first part 72 and a second part 74. The first part 72 is located in the trace region R1, the second part 74 is located in the terminal region R2, and the first part 72 and the second part 74 have different patterns. In some embodiments, the first part 72 and the second part 74 may have the same pattern. In one embodiment, the first part 72 may have a plane pattern (i.e. without any opening), or a pattern consisting of lines, waves, rectangles, sawtooth, meshes, curves, or irregular shapes, but not limited thereto. In one embodiment, the second part 74 may have a plane pattern (i.e. without any opening), or a pattern consisting of lines, waves, rectangles, sawtooth, meshes, curves, or irregular shapes, but not limited thereto. It should be noted that, the “pattern” is defined for the electrode. The electrodes are said to have “different patterns” if the electrodes have different shapes and areas. For example, the mesh pattern is different from the pattern of lines, the plane pattern is different from the pattern of lines, the pattern of thick lines is different from the pattern of thin lines, and the mesh pattern of thick lines is different from the mesh pattern of thin lines. It should be noted that, whether the electrodes have different patterns is determined in regions of substantially equal area. For example, after respective equal areas are selected for the first part 72 and the second part 74, the shapes and the areas of the respective electrode patterns of the first part 72 and the second part 74 can be compared. The following description will discuss how the first part 72 and the second part 74 have different patterns in the embodiments of FIGS. 4B, 5A, and 5B.

In the embodiment of FIG. 4B, the first part 72 of the patterned electrode layer 70 is a plane electrode in Z-direction, i.e. having a plane pattern. The trace part 622 overlaps the electrode of the first part 72 of the patterned electrode layer 70 in Z-direction. It should be noted that, one component A is said to overlap another component B in the present disclosure, not only when the component A is aligned with the component B, but also when the component A at least partially overlaps the component B in Z-direction. Moreover, in FIG. 4B, the second part 74 in the patterned electrode layer 70 has a stripe pattern in Z-direction. In FIG. 4B, the number of stripe electrodes of the second part 74 may be equal to the number of the terminal part 624 of the wire 62. Each stripe electrode may partially overlap one terminal part 624, but not limited thereto. In some embodiments, a stripe electrode of the second part 74 may have a width in X-direction that is equal to or greater than the width of the terminal part in X-direction, but not limited thereto.

In the embodiment of FIG. 5A, the first part 72 of the patterned electrode layer 70 has a plane pattern in Z-direction, as in the embodiment of FIG. 4A. Moreover, the second part 74 of the patterned electrode layer 70 has a mesh pattern in Z-direction, i.e. having a plurality of openings. The mesh electrode of the second part 74 at least partially overlaps the terminal part 624. In this design, the ratio of the first overlapping area A to the second overlapping area B is between 0.7 and 1.3, i.e. 0.7≤A/B≤1.3. The capacitance between the patterned electrode layer 70 and the terminal part 624 is substantially equal to the capacitance between the patterned electrode layer 70 and the trace part 622. This can reduce the impedance difference (and the differential impedance) in the terminal part 624 and the trace part 622, and improve the signal transmission quality.

In the embodiment of FIG. 5B, the first part 72 of the patterned electrode layer 70 has a plane pattern in Z-direction. Moreover, the second part 74 of the patterned electrode layer 70 has a stripe pattern in Z-direction. The stripe electrodes of the second part 74 are located between the two terminal parts 624. The stripe electrodes of the second part 74 partially overlap the two terminal parts 624, respectively. In this design, the ratio of the first overlapping area A to the second overlapping area B is between 0.7 and 1.3, i.e. 0.7≤A/B≤1.3. The capacitance between the patterned electrode layer 70 and the terminal part 624 is substantially equal to the capacitance between the patterned electrode layer 70 and the trace part 622. This can reduce the impedance difference (and the differential impedance) in the terminal part 624 and the trace part 622, and improve the signal transmission quality.

Moreover, in some embodiments, the patterned electrode layer 70 may include at least one stripe electrode. In the embodiments of MS. 5C to 5F, the patterned electrode layer 70 may consist of a plurality of stripe electrodes, and one of the stripe electrodes may partially overlap the trace part 622 and the terminal part 624 in Z-direction. The following description will discuss the embodiments of FIGS. 5C to 5F in detail.

In the embodiment of FIG. 5C, the patterned electrode layer 70 consists of a plurality of stripe electrodes 73. One of the stripe electrodes 73 corresponds to one of the wires 62, but not limited thereto. In some embodiments, the trace part 622 and the terminal part 624 have substantially equal width in X-direction. For example, as shown in FIG. 5C, the stripe electrodes 73 extend in Y-direction. One of the stripe electrodes 73 has a first width W1. The first width W1 may be defined to be a greatest width of the stripe electrode 73 in X-direction of a local region. Moreover, as shown in FIG. 5C, the width of the stripe electrode 73 in the trace region R1 is substantially equal to the width of the strip electrode 73 in the terminal region R2. In this case, the first part 72 and the second part 74 have substantially the same pattern. Moreover, the width of the trace part 622 of the wire 62 is substantially equal to the width of the terminal part 624. The trace part 622 has a second width W2. The second width W2 may be defined to be a greatest width of the trace part 622 in X-direction of a local region. In FIG. 5C, the ratio of the first width W1 to the second width W2 is between 0.3 and 1, i.e. 0.3≤≤1, and thus the first width W1 is less (or smaller) than the second width W2. The stripe electrodes 73 may at least partially overlap the wires 62, respectively, in Z-direction. In some embodiments, the ratio of the first width W1 to the second width W2 is between 0.5 and 1, i.e. 0.5≤W1/W2≤1. In this design, the ratio of the first overlapping area A to the second overlapping area B is between 0.7 and 1.3. The capacitance between the patterned electrode layer 70 and the terminal part 624 is substantially equal to the capacitance between the patterned electrode layer 70 and the trace part 622. This can reduce the impedance difference (and the differential impedance) in the terminal part 624 and the trace part 622, and improve the signal transmission quality.

In the embodiment of FIG. 5D, the patterned electrode layer 70 consists of a plurality of stripe electrodes 73. One of the stripe electrodes 73 corresponds to or at least partially overlaps one of the wires 62. The trace part 622 and the terminal part 624 have different widths in X-direction. In the embodiment of FIG. 5D, the stripe electrode 73 has a first width W1 as previously defined. The trace part 622 has a second width W2 as previously defined. The terminal part 624 has a third width W3. The third width W1 may be defined to be a greatest width of the terminal part 624 in X-direction, particularly of a local region. In this embodiment, the ratio of the first width W1 to the second width W2 is between 0.7 and 1.3, i.e. 0.7≤W1/W2≤1.3. In some embodiments, the ratio of the first width W1 to the second width W2 is between 0.8 and 1.2, i.e. 0.8≤W1/W2≤1.2, between 0.9 and 1.1, i.e. 0.9≤W1/W2≤1.1, between 0.95 and 1.05, i.e. 0.95≤W1/W2≤1.05, or between 0.98 and 1.02, i.e. 0.98≤W1/W2≤1.02, but not limited thereto. Moreover, in one embodiment, the third width W3 may be greater than the second width W2, but not limited thereto. It should be noted that, the greatest width or the greatest pitch of the component in the local region may be defined based on the greatest width of the component measured in an OM image, wherein the image may be set to have a length and a width between 0.5 mm and 500 mm. Any other suitable measurement is also applicable.

In the embodiment of FIG. 5E, the patterned electrode layer 70 consists of a plurality of stripe electrodes 73. One of the stripe electrodes 73 corresponds to or at least partially overlaps one of the wires 62. The trace part 622 and the terminal part 624 have unequal widths in X-direction. As shown in FIG. 5E, the terminal part 624 has at least one opening O. The opening O is rectangular in Z-direction, and the terminal part 624 is thus a rectangular terminal part electrode in Z-direction, but not limited thereto. In one embodiment, the opening O of the terminal part 624 may have an arc shape, a sharp shape, a mesh shape, or any other irregular shape, but not limited thereto. Moreover, in FIG. 5E, the stripe electrode 73 has a first width W1, defined as previously discussed. The trace part 622 has a second width W2, defined as previously discussed. The ratio of the first width W1 to the second width W2 is similar to that shown in FIG. 5D, and will not be discussed again here. In this design, the ratio of the first overlapping area A to the second overlapping area B is between 0.7 and 1.3. The capacitance between the patterned electrode layer 70 and the terminal part 624 is substantially equal to the capacitance between the patterned electrode layer 70 and the trace part 622. This can reduce the impedance difference (and the differential impedance) in the terminal part 624 and the trace part 622, and improve the signal transmission quality.

In the embodiment of FIG. 5F, the patterned electrode layer 70 consists of at least one stripe electrode. One of the stripe electrodes 64 is located between the two wires 62. One of the stripe electrodes 64 partially overlaps one of the two wires 62 in Z-direction. The stripe electrode 73 has a first width W1, defined as previously discussed. Moreover, in this embodiment, the trace part 622 and the terminal part 624 have equal width in X-direction. The trace part 622 has a second width W2, defined as previously discussed. In this design, the ratio of the first overlapping area A and the second overlapping area B is between 0.8 and 1.2. The capacitance between the patterned electrode layer 70 and the terminal part 624 is substantially equal to the capacitance between the patterned electrode layer 70 and the trace part 622. This can reduce the impedance difference (and the differential impedance) in the terminal part 624 and the trace part 622, and improve the signal transmission quality.

It should be noted that, when the width of the trace part and is substantially equal to the width of the terminal part, and the pitch between the two adjacent trace parts is substantially equal to the pitch between the two adjacent terminal parts, it is possible to define the terminal region R2 by the region of the stiffener on the circuit board, but not limited thereto.

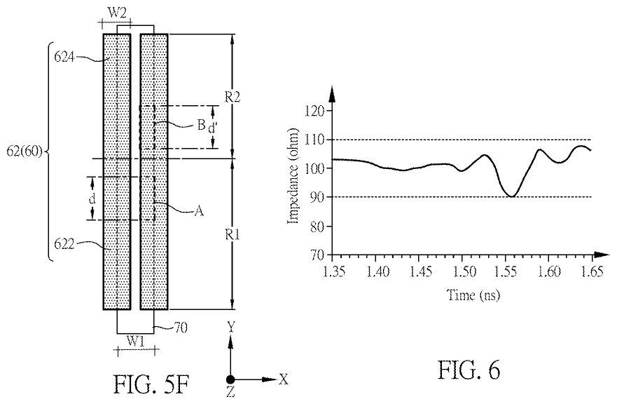

FIG. 6 is a graph showing a relationship between impedance (e.g. differential impedance) and time measured by TDR of the circuit board 50 according to one embodiment of the present disclosure, wherein the circuit board 50 of FIG. 4A is used in this case for example. As shown in FIG. 6, in the signal transmission process, the impedances of the trace part or the terminal part of the wire 62 are both between 90 ohm and 110 ohm, i.e. 90 ohm≤impedance≤110 ohm, and the ratio of the first (differential) impedance to the second (differential) impedance is between 0.9 and 1.1, i.e. 0.9≤ratio≤1.1, but not limited thereto. In some embodiments, the ratio of the first (differential) impedance to the second (differential) impedance is between 0.92 and 1.08, i.e. 0.92≤ratio≤1.08. The present disclosure provides a design that can reduce the impedance difference (and differential impedance) in the trace part and the terminal part, improve the impedance matching, and solve the problem of signal reflection or signal jitter in the circuit board.

Moreover, in some embodiments, the trace part 622 may have different widths in X-direction. The trace part 622 may have two trace portions having different widths, and the ratio of their respective overlapping areas that overlap the patterned electrode layer 70 is between 0.7 and 1.3. The overlapping areas are measured in a similar way when measuring the first overlapping area or the first overlapping area, and the measurement will not be discussed here again. For example, one trace portion of the trace part 622 may be designed to support an electronic component, and thus it may require a greater width. Then, the trace portion having the greater width overlaps the patterned electrode layer 70 in one overlapping area, and another trace portion overlaps the patterned electrode layer 70 in another overlapping area, and the ratio of the overlapping areas is between 0.7 and 1.3. The electronic component may be a protective component, but not limited thereto. This avoids impedance difference even if the trace part 622 has different portions having different widths, and improves the signal transmission quality.

The electronic device 1 of the present disclosure is applicable to any device that involves signal transmission, such as a display, a cellphone, a laptop, a video camera, a photo camera, a music player, a mobile navigator, a television, a vehicle dashboard, a center console, an electronic rearview mirror, or a dead up display, but not limited thereto.

Although the present disclosure has been explained in relation to the aforementioned embodiments, it is to be understood that many other possible modifications and variations can be made without departing from the spirit of the present disclosure and the scope as hereinafter claimed.

What is claimed is:

1. An electronic device, comprising:
a circuit board including:
a wiring layer including a plurality of wires, one of the plurality of wires including a trace part and a terminal part connected to the trace part; and
a patterned electrode layer disposed opposite to the wiring layer;
wherein, the trace part and the patterned electrode layer have a first overlapping area, the terminal part and the patterned electrode layer have a second overlapping area, and a ratio of the first overlapping area to the second overlapping area is between 0.7 and 1.3.

2. The electronic device of claim 1, wherein the patterned electrode layer includes a plurality of stripe electrodes, and one of the stripe electrodes overlaps at least a part of the trace part and at least a part of the terminal part.

3. The electronic device of claim 2, wherein one of the plurality of stripe electrodes has a first width, the trace part has a second width, and a ratio of the first width to the second width is between 0.7 and 1.3.

4. The electronic device of claim 2, wherein one of the plurality of stripe electrodes has a first width, the trace part has a second width, and the first width is less than the second width.

5. The electronic device of claim 2, wherein one of the plurality of stripe electrodes is located between two adjacent wires of the plurality of wires, and overlaps the two adjacent wires.

6. The electronic device of claim 1, wherein the circuit board has a trace region and a terminal region, the patterned electrode layer has a first part and a second part, wherein the first part is located in the trace region, the second part is located in the terminal region, and a pattern of the first part is different from a pattern of the second part.

7. The electronic device of claim 1, wherein the trace part has a first differential impedance, the terminal part has a second differential impedance, and a ratio of the first differential impedance to the second differential impedance is between 0.9 and 1.1.

8. The electronic device of claim 1, wherein the trace part has a first differential impedance, the terminal part has a second differential impedance, and the second differential impedance is less than the first differential impedance.

9. The electronic device of claim 1, wherein a capacitance between the patterned electrode layer and the terminal part is substantially equal to a capacitance between the patterned electrode layer 70 and the trace part.

10. The electronic device of claim 1, further comprising another trace part adjacent to the trace part, wherein a pitch between the two adjacent trace parts varies along an extending direction of the trace parts.

11. The electronic device of claim 1, further comprising another trace part adjacent to the trace part, a greater pitch appears between two connecting portions 231c of the two adjacent trace parts.

12. An electronic device, comprising:
a circuit board including a wiring layer, the wiring layer including a first reference wire, a second reference wire, a first group of wires, and a second group of wires;
wherein the second group of wires is adjacent to the first group of wires, and the first group of wires and the second group of wires are located between the first reference wire and the second reference wire.

13. The electronic device of claim 12, wherein the circuit board further includes an electrode layer disposed opposite to the wiring layer, the circuit board has a trace region and a terminal region, and the electrode layer is located in the trace region.

14. The electronic device of claim 13, wherein a part of the wiring layer is located in the trace region, and another part of the wiring layer is located in the terminal region.

15. The electronic device of claim 13, wherein the first reference wire and the second reference wire are electrically connected to the electrode layer.

16. The electronic device of claim 13, wherein the circuit board further includes a stiffener located in the terminal region.

17. The electronic device of claim 13, wherein the circuit board further includes a dielectric layer disposed between the wiring layer and the electrode layer.

18. The electronic device of claim 13, wherein the electrode layer has a mesh pattern.

19. The electronic device of claim 12, the first group of wires is used to transmit a plurality of differential signals.

20. The electronic device of claim 12, one of the wires in the first group of wires is used to transmit a single-ended signal.
